(19) United States
(12) Patent Application Publication
(10) Pub. No.: US 2002/0085404 A1
(43) Pub. Date: Jul. 4, 2002

(54) Smart random access memory

(76) Inventors: Shao-Chun Lu, Hsinchu Hsien (TW); Wen-Chien Huang, Hsinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/753,604

(22) Filed: Jan. 4, 2001

(51) Int. Cl. G11C 5/02

(52) U.S. Cl. 365/51

(57) ABSTRACT

The present invention proposes a smart RAM formed by assembling memory arrays of different functions. The smart RAM comprises mainly a first memory array, a second memory array, and a buffer memory array. The first memory array is mainly used to store large data or resident data. The second memory array is mainly used to store small data or commonly used data. The buffer memory array is connected between the first and second memory arrays and is mainly used as an array for fast shifting of data stored in the first and second memory arrays to accomplish the transfer and communication of signals between each memory. The smart RAM comprising memory arrays of different types has the function of automatically judging the characteristics of data, and also has the advantage of letting the operation of a microprocessor be faster and power-saving.

### FIELD OF THE INVENTION

The present invention relates to a memory and, more particularly, to a smart random access memory (RAM) having dual memory functions.

### BACKGROUND OF THE INVENTION

Along with continual progress of semiconductor technology, types of memories become more and more. According to the way of supplying electricity, memory can be simply divided into two types: volatile memory and non-volatile memory. Power supply for the volatile memory must be unceasing to prevent data stored therein from disappearing. According to the way of processing data, the volatile memory can further be divided into two types: dynamic random access memory (DRAM) and static random access memory (SRAM). Contrarily, the non-volatile memory is characterized in that data stored therein will not disappear even the power supply is interrupt. According to the way of storing data, the non-volatile memory can be further divided into mask read-only memory (mask ROM), programmable ROM (PROM), erasable programmable ROM (EPROM), electrically erasable programmable ROM (EEPROM), and flash memory. Because all these memories have their individual ways of storing data, their applications differ from one another. Volatile memories are generally used for storing commonly used data, while non-volatile memories are generally used for storing resident data. Memories for different applications are matched on a computer system and connected one another via external lines to meet to the requirement of the computer system.

Along with more powerfill functions of microprocessors and huger programs and operations performed therein, the requirement for memories of large pg,3 quantity and high speed becomes more pressing. Because the above memories of various types having individual functions must be connected via external lines to communicate information, there is a certain limit on the speed of communication of information, thereby not contenting the requirement of high-speed operation of consumers. Additionally, the space for accommodating memories for a general computer is limited, the types of installed memories are thus limited so as to influence the operation of the whole computer. The present invention aims to propose a smart RAM to resolve the above problems.

### SUMMARY OF THE INVENTION

The primary object of the present invention is to provide a smart RAM having dual memory functions and capable of automatically judging the characteristics of data.

Another object of the present invention is to provide a smart RAM so that the operation of a microprocessor will be fast and power-saving.

According to the present invention, a smart RAM is formed by assembling memory arrays of different functions. The smart RAM comprises mainly a first memory array, a second memory array, and a buffer memory array. The first memory array is mainly used to store large data or resident data. The second memory array is mainly used to store small data or commonly used data. The buffer memory array is connected between the first and second memory arrays and is mainly used as an array for fast shifting of data stored in the first and second memory arrays to accomplish the transfer and communication of signals between each memory.

The various objects and advantages of the present invention will be more readily understood from the following detailed description when read in pg,4 conjunction with the appended drawings, in which:

### BRIEF DESCRIPTION OF THE DRAWINGS:

FIG. 1 is a structure diagram of the smart RAM of the present invention; and

FIG. 2 is a diagram of the smart RAM according to an embodiment of the present invention.

### DETAILED DESCRIPTION OF THE PREFERRED EMBODIMENTS

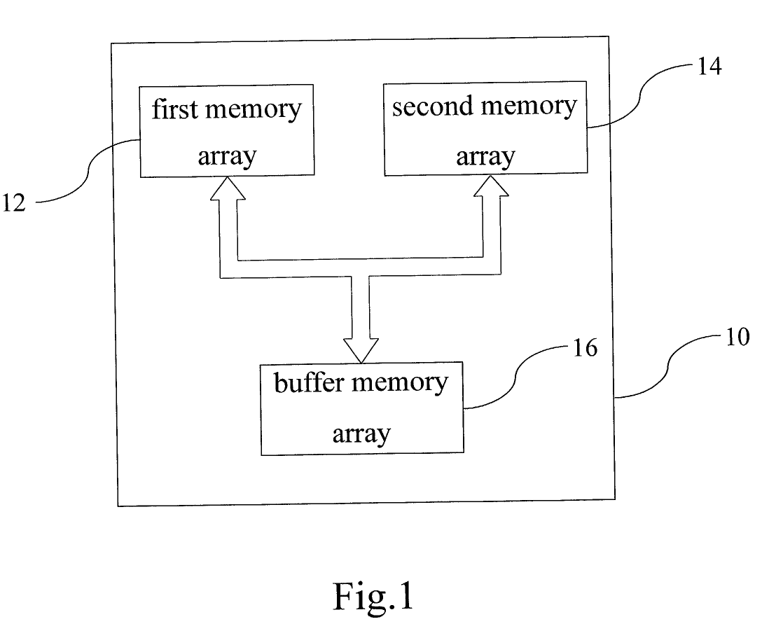

As shown in FIG. 1, a smart RAM 10 is formed by assembling three memory arrays having different functions and composed of memory cells. The smart RAM 10 comprises mainly a first memory array 12, a second memory array 14, and a buffer memory array 16. The first memory array 12 is mainly used to store large data or resident data. The second memory array 14 is mainly used to store small data or commonly used data. The buffer memory array 16 is connected between the first and second memory arrays 12 and 14. The buffer memory array 16 is mainly used as an array for fast shifting of data stored in the first and second memory arrays 12 and 14 to accomplish the transfer and communication of signals between each memory. The buffer memory array 16 also has the function of automatically judging whether the data to be stored is resident data or commonly used data so as to store this data into the first memory array 12 or the second memory array 14.

For the smart RAM 10 comprising memory arrays for different applications, the buffer memory array 16 designed on the smart RAM 10 is exploited for transfer actions of data stored in memory arrays of different types. The characteristics of fast operation and power saving can thus be obtained as compared with the transfer actions of data via external lines between two memories in prior art. Furthermore, because the functions of a smart RAM 10 pg,5 can replace the functions obtained by matching different memories in prior art, a smart RAM 10 can replace a plurality of memories in prior art. The advantage of space saving in installment can be obtained.

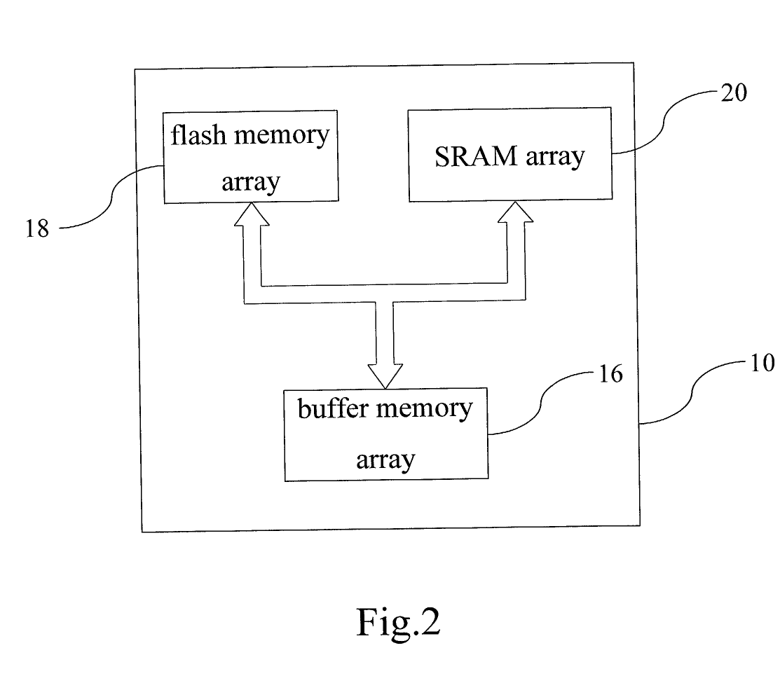

The first memory array 12 for storing resident data has the same characteristics as those of a non-volatile memory. The stored data will not disappear even the power supply is interrupt. The second memory array 14 has the same characteristics as those of a volatile memory. The stored data will disappear if the power supply is interrupt. As shown in FIG. 2, the first memory array can be a flash memory array 18 having properties similar to those of a flash memory. The second memory array can be an SRAM array 20 having properties similar to those of an SRAM. Thereby, except having the function of randomly accessing data, the smart RAM 10 comprising the memory arrays 18 and 20 and the buffer memory array 16 also has the function of keeping data required to be resident such as the basic input/output system (BIOS) of a computer or the telephone book of a mobile phone when the power supply is interrupt.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims. pg,6

I claim:

1. A smart random access memory formed by assembling memory arrays having different functions and composed of memory cells, said smart random access memory comprising:
a first memory array used for storing large data or resident data;
a second memory array used for storing small data or commonly used data; and
a buffer memory array connected between said first memory array and said second memory array, said buffer memory array being used as an array for fast shifting of data stored in said first memory array and said second memory array.
